(19) United States
(12) Patent Application Publication
(10) Pub. No.: US 2026/0096315 A1
(43) Pub. Date: Apr. 2, 2026

(54) DISPLAY DEVICE INCLUDING STRESS RELIEVING PATTERN

(71) Applicant: LG Display Co., Ltd., Seoul (KR)

(72) Inventors: Seong-Hwan WOO, Paju-si (KR); Dong-Hun JUNG, Paju-si (KR)

(73) Assignee: LG Display Co., Ltd., Seoul (KR)

(21) Appl. No.: 19/277,146

(22) Filed: Jul. 22, 2025

(30) Foreign Application Priority Data
Oct. 2, 2024 (KR) 10-2024-0133704

(51) Int. Cl. H10K 59/131; H10K 59/40

(52) U.S. Cl. CPC H10K 59/131; H10K 59/40

(57) ABSTRACT

A display device including a stress relieving pattern in an example includes a display panel having a display area and a non-display area at a periphery of the display area, a plurality of gate lines and a plurality of data lines in the display area and crossing each other to define a plurality of subpixels, at least one thin film transistor in each of the plurality of subpixels, first and second power lines in the non-display area and each having a hammer pattern of an uneven shape, and a stress relieving pattern covering the hammer pattern at facing sides of the first and second power lines.

### CROSS-REFERENCE TO RELATED APPLICATION

The present application claims priority to Korean Patent Application No. 10-2024-0133704, filed in the Republic of Korea on October 2, 2024, which is hereby expressly incorporated by reference in its entirety.

### BACKGROUND

### Technical Field

The present disclosure relates to a display device, and more particularly, to a display device including a stress relieving pattern.

### Discussion of the Related Art

Recently, various flat panel display devices such as a liquid crystal display device (LCD), an organic light emitting diode (OLED) display device and a field emission display (FED) device having excellent properties of a thin profile, a light weight and a low power consumption have been developed and applied to various fields.

A display device includes a display panel for displaying an image and a driving unit for supplying a signal and a power to the display panel. The driving unit includes a gate driving unit and a data driving unit for supplying a gate voltage and a data voltage, respectively, to each pixel of the display panel.

The display device further includes a hammer pattern at a side of a power line for preventing permeation of an impurity of an exterior. However, a seam is formed in an insulating layer over the hammer pattern due to a step difference of the hammer pattern, and a crack can be generated from the seam due to a contraction and an expansion of an upper layer or an external impact. As a result, deterioration such as a permeation of an oxygen or a moisture can occur.

### SUMMARY OF THE DISCLOSURE

Accordingly, the present disclosure is directed to a display device that substantially obviates one or more of the problems due to limitations and disadvantages of the related art.

The present disclosure is to provide a display device where a formation of a seam in an insulating layer is minimized, a stress is relieved, and a generation of a crack is minimized by forming a stress relieving pattern on a hammer pattern.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes a display panel having a display area and a non-display area at a periphery of the display area, a plurality of gate lines and a plurality of data lines in the display area and crossing each other to define a plurality of subpixels, at least one thin film transistor in each of the plurality of subpixels, a first power line and a second power line in the non-display area and each having a hammer pattern of an uneven shape, and a first stress relieving pattern covering the hammer pattern at facing sides of the first and second power lines.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

In the drawings:

FIG. 1 is a view showing a display device according to an embodiment of the present disclosure;

FIG. 2 is a circuit diagram showing a subpixel of a display device according to an embodiment of the present disclosure;

FIG. 3 is a cross-sectional view showing a subpixel of a display panel of a display device according to an embodiment of the present disclosure;

FIG. 4 is a plan view showing a display panel and a data driving unit of a display device according to an embodiment of the present disclosure;

FIG. 5 is a magnified view of a portion A of FIG. 4 according to an example of the present disclosure;

FIG. 6 is a cross-sectional view taken along a line VI-VI of FIG. 5 according to an example of the present disclosure;

FIG. 7 is a cross-sectional view taken along a line VII-VII of FIG. 5 according to an example of the present disclosure;

FIG. 8 is a cross-sectional view showing a hammer pattern and a first stress relieving pattern of a display device according to an embodiment of the present disclosure;

FIG. 9 is a magnified view of a portion B of FIG. 4 according to an example of the present disclosure; and

FIG. 10 is a cross-sectional view taken along a line X-X of FIG. 9 according to an example of the present disclosure.

### DETAILED DESCRIPTION OF THE EMBODIMENTS

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure can be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example aspects of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration can unnecessarily obscure a feature or aspect of the present disclosure, a detailed description of such known function or configuration can be omitted or a brief description can be provided.

Where the terms "comprise," "have," "include," and the like are used, one or more other elements can be added unless the term, such as "only," is used. An element described in the singular form is intended to include a plurality of elements, and vice versa, unless the context clearly indicates otherwise. Further, the term “can” fully encompasses all the meanings and coverages of the term “may” and vice versa.

In construing an element, the element is to be construed as including an error or a tolerance range even where no explicit description of such an error or tolerance range is provided.

Where positional relationships are described, for example, where the positional relationship between two parts is described using "on," "over," "under," "above," "below," "beside," "next," or the like, one or more other parts can be located between the two parts unless a more limiting term, such as "immediate(ly)," "direct(ly)," or "close(ly)" is used. For example, where an element or layer is disposed "on" another element or layer, a third layer or element can be interposed therebetween.

Although the terms "first," "second," A, B, (a), (b), and the like can be used herein to refer to various elements, these elements should not be interpreted to be limited by these terms as they are not used to define a particular order or precedence. These terms are only used to distinguish one element from another and may not define order or sequence. For example, a first element could be termed a second element, and, similarly, a second element could be termed a first element, without departing from the scope of the present disclosure.

The term "at least one" should be understood to include all combinations of one or more of related elements. For example, the term of "at least one of first, second and third elements" can include all combinations of two or more of the first, second and third elements as well as the first, second or third element.

The term "display device" can include a display device in a narrow sense such as liquid crystal module (LCM), an organic light emitting diode (OLED) module and a quantum dot (QD) module including a display panel and a driving unit for driving the display panel. In addition, the term "display device" can include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure can include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit can be expressed as "a display device", and an electronic apparatus of a complete product including the LCM, the OLED module and the QD module can be expressed as "a set device." For example, a display device in a narrow sense can include a display panel of a liquid crystal, an organic light emitting diode and a quantum dot and a source printed circuit board (PCB) of a control unit for driving the display panel, and a set device can further include a set PCB of a set control unit electrically connected to the source PCB for controlling the entire set device.

The display panel of the present disclosure can include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel can include a plurality of gate lines, a plurality of data lines and a subpixel in a crossing region of the plurality of gate lines and the plurality of data lines. The display panel can include an array having a thin film transistor of an element for selectively applying a voltage to each subpixel, an emitting element layer on the array and an encapsulating substrate or an encapsulation part covering the emitting element layer. The encapsulation part can protect the thin film transistor and the emitting element layer from an external impact and can prevent or at least reduce penetration of a moisture or oxygen into the emitting element layer. In addition, the emitting element layer on the array can include an inorganic light emitting layer, for example, a nano-sized material layer or a quantum dot.

The thin film transistor of the present disclosure can include one of an oxide thin film transistor, an amorphous silicon thin film transistor, and a low temperature polycrystalline silicon thin film transistor.

Features of various embodiments of the present disclosure can be partially or entirely coupled to or combined with each other. They can be linked and operated technically in various ways as those skilled in the art can sufficiently understand. The aspects can be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings. All the components of each display device according to all embodiments of the present disclosure are operatively coupled and configured.

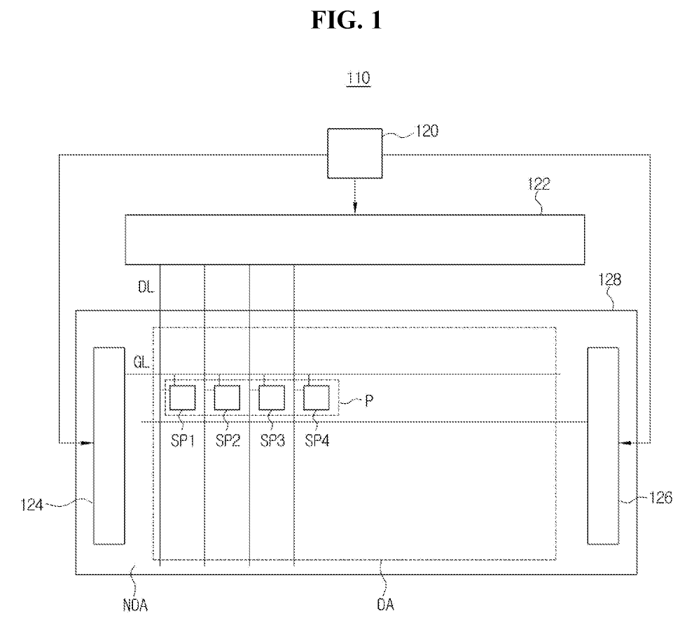

FIG. 1 is a view showing a display device according to an embodiment of the present disclosure. Although the display device can be an organic light emitting diode (OLED) display device, it is not limited thereto. For example, the display device can be a quantum dot (QD) display device, a micro light emitting diode (LED) display device or a mini light emitting diode (LED) display device.

In FIG. 1, a display device 110 according to an embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data (RGB), a data control signal and a gate control signal using an image signal and a plurality of timing signals including a data enable signal, a horizontal synchronization signal, a vertical synchronization signal and a clock signal transmitted from an external system such as a graphic card or a television system. The timing controlling unit 120 transmits the image data and the data control signal to the data driving unit 122, and transmits the gate control signal to the first and second gate driving units 124 and 126.

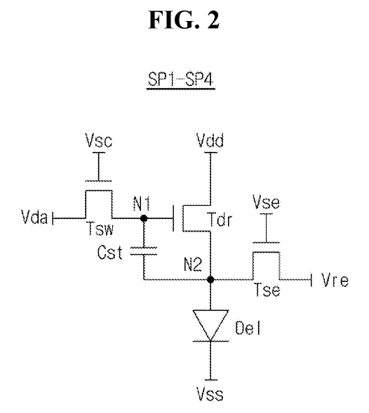

The data driving unit 122 generates a data signal (a data voltage) Vda (of FIG. 2) using the image data and the data control signal transmitted from the timing controlling unit 120 and transmits the data signal Vda to a data line DL of the display panel 128.

The first and second gate driving units 124 and 126 generate a gate signal (a gate voltage) Vsc and Vse (of FIG. 2) using the gate control signal transmitted from the timing controlling unit 120 and applies the gate signal Vsc and Vse to a gate line GL of the display panel 128.

The first and second gate driving units 124 and 126 can have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the embodiment of FIG. 1, one gate driving unit can be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. For displaying an image, the display panel 128 includes a plurality of pixels P, a plurality of gate lines GL and a plurality of data lines DL in the display area DA.

Each of the plurality of pixels P includes first, second, third and fourth subpixels SP1, SP2, SP3 and SP4, and the gate line GL and the data line DL cross each other to define the first, second, third and fourth subpixels SP1, SP2, SP3 and SP4. Each of the first, second, third and fourth subpixels SP1, SP2, SP3 and SP4 is connected to the gate line GL and the data line DL. For example, the first, second, third and fourth subpixels SP1, SP2, SP3 and SP4 can correspond to red, green, blue and white colors, respectively.

Each of the first, second, third and fourth subpixels SP1, SP2, SP3 and SP4 can include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode Del (of FIG. 2).

FIG. 2 is a circuit diagram showing a subpixel of a display device according to an embodiment of the present disclosure.

In FIG. 2, each of the first, second, third and fourth subpixels SP1, SP2, SP3 and SP4 of the display panel 128 of the display device 110 according to an embodiment of the present disclosure includes a switching transistor Tsw, a driving transistor Tdr, a sensing transistor Tse, a storage capacitor Cst and a light emitting diode Del.

Although each of the first, second, third and fourth subpixels SP1, SP2, SP3 and SP4 has a 3T1C structure having three transistors and one storage capacitor in the embodiment of FIG. 2, each of the first, second, third and fourth subpixels SP1, SP2, SP3 and SP4 can have one of a 6T1C structure having six transistors and one storage capacitor, a 7T1C structure having seven transistors and one storage capacitor and a 8T1C structure having eight transistors and one storage capacitor in another embodiment.

Although the switching transistor Tsw, the driving transistor Tdr and the sensing transistor Tse can have a negative type in the embodiment of FIG. 2, at least one of the switching transistor Tsw, the driving transistor Tdr and the sensing transistor Tse can have a positive type in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N2 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vda supplied to the first node N1 for one frame and stores a threshold voltage (Vth) of the driving transistor Tdr.

A first capacitor electrode of the storage capacitor Cst is connected to the first node N1, and a second capacitor electrode of the storage capacitor Cst is connected to the second node N2.

The light emitting diode Del emits a light of a luminance proportional to a current of the driving transistor Tdr.

An anode of the light emitting diode Del is connected to the second node N2, and a cathode of the light emitting diode Del is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and anode of the light emitting diode Del constitute the second node N2.

The light emitting diode Del can display an image having a luminance corresponding to the image data (RGB) according to a driving of subpixel circuits of the first, second, third and fourth subpixels SP1, SP2, SP3 and SP4.

A cross-sectional structure of each subpixel SP1, SP2, SP3 and SP4 of the display panel 128 of the display device 110 will be illustrated with reference to the drawings.

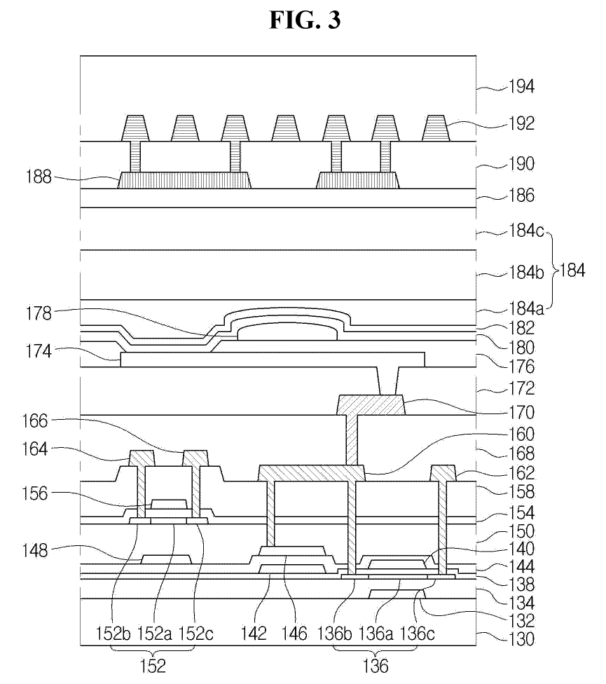

FIG. 3 is a cross-sectional view showing a subpixel of a display panel of a display device according to an embodiment of the present disclosure.

In FIG. 3, a first light shielding pattern 132 is disposed in each of the first, second, third and fourth subpixels SP1, SP2, SP3 and SP4 on a substrate 130, and a first buffer layer 134 is disposed on the first light shielding pattern 132 over the entire substrate 130.

The first light shielding pattern 132 can block a light incident from a lower portion of the substrate 130. For example, the first light shielding pattern 132 can have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

The first buffer layer 134 can block a moisture or an oxygen permeating from an exterior. For example, the first buffer layer 134 can have a single layer or a multiple layer of an inorganic insulating material such as silicon oxide (SiO₂) and silicon nitride (SiNx).

A first semiconductor layer 136 is disposed on the first buffer layer 134 corresponding to the first light shielding pattern 132, and a first gate insulating layer 138 is disposed on the first semiconductor layer 136 over the entire substrate 130.

The first semiconductor layer 136 includes a first channel region 136a not doped with an impurity at a central portion thereof and first source and drain regions 136b and 136c doped with an impurity at both side portions of the first channel region 136a. For example, the first semiconductor layer 136 can include a polycrystalline semiconductor material such as polycrystalline silicon

For example, the first gate insulating layer 138 can have a single layer or a multiple layer of an inorganic insulating material such as silicon oxide (SiO₂) and silicon nitride (SiNx).

A first gate electrode 140 is disposed on the first gate insulating layer 138 corresponding to the first channel region 136a of the first semiconductor layer 136, a first capacitor electrode 142 separated from the first gate electrode 140 is disposed on the first gate insulating layer 138, and a first interlayer insulating layer 144 is disposed on the first gate electrode 140 and the first capacitor electrode 142.

The first gate electrode 140 and the first capacitor electrode 142 can have the same layer and the same material as each other. For example, the first gate electrode 140 and the first capacitor electrode 142 can have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the first interlayer insulating layer 144 can have a single layer or a multiple layer of an inorganic insulating material such as silicon oxide (SiO₂) and silicon nitride (SiNx).

A second capacitor electrode 146 is disposed on the first interlayer insulating layer 144 corresponding to the first capacitor electrode 142, a second light shielding pattern 148 separated from the second capacitor electrode 146 is disposed on the first interlayer insulating layer 144, and a second buffer layer 150 is disposed on the second capacitor electrode 146 and the second light shielding pattern 148 over the entire substrate 130.

The second capacitor electrode 146 and the second light shielding pattern 148 can have the same layer and the same material as each other. For example, the second capacitor electrode 146 and the second light shielding pattern 148 can have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

The first capacitor electrode 142, the first interlayer insulating layer 144 and the second capacitor electrode 146 can constitute the storage capacitor Cst.

The second buffer layer 150 can block a moisture or an oxygen permeating from an exterior. For example, the second buffer layer 150 can have a single layer or a multiple layer of an inorganic insulating material such as silicon oxide (SiO₂) and silicon nitride (SiNx).

A second semiconductor layer 152 is disposed on the second buffer layer 150 corresponding to the second light shielding pattern 148, and a second gate insulating layer 154 is disposed on the second semiconductor layer 152 over the entire substrate 130.

The second semiconductor layer 152 includes a second channel region 152a not conductorized at a central portion thereof and second source and drain regions 152b and 152c conductorized at both side portions of the second channel region 152a. For example, the second semiconductor layer 152 can include an oxide semiconductor material such as indium gallium zinc oxide (IGZO), zinc oxide (ZnO), tin oxide (SnO₂), copper oxide (Cu₂O), nickel oxide (NiO), indium tin zinc oxide (ITZO) and indium aluminum zinc oxide (IAZO).

For example, the second gate insulating layer 154 can have a single layer or a multiple layer of an inorganic insulating material such as silicon oxide (SiO₂) and silicon nitride (SiNx).

A second gate electrode 156 is disposed on the second gate insulating layer 154 corresponding to the second channel region 152a of the second semiconductor layer 152, and a second interlayer insulating layer 158 is disposed on the second gate electrode 156 over the entire substrate 130.

For example, the second gate electrode 156 can have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the second interlayer insulating layer 158 can have a single layer or a multiple layer of an inorganic insulating material such as silicon oxide (SiO₂) and silicon nitride (SiNx).

A first source electrode 160, a first drain electrode 162, a second source electrode 164 and a second drain electrode 166 spaced apart from each other are disposed on the second interlayer insulating layer 158, and a first planarizing layer 168 is disposed on the first source electrode 160, the first drain electrode 162, the second source electrode 164 and the second drain electrode 166 over the entire substrate 130.

The first source electrode 160 and the first drain electrode 162 are connected to the first source region 136b and the first drain region 136c, respectively, of the first semiconductor layer 136 through contact holes in the second interlayer insulating layer 158, the second gate insulating layer 154, the second buffer layer 150, the first interlayer insulating layer 144 and the first gate insulating layer 138. The first source electrode 160 is connected to the second capacitor electrode 146 through a contact hole in the second interlayer insulating layer 158, the second gate insulating layer 154 and the second buffer layer 150.

The second source electrode 164 and the second drain electrode 166 are connected to the second source region 152b and the second drain region 152c, respectively, of the second semiconductor layer 152 through contact holes in the second interlayer insulating layer 158 and the second gate insulating layer 154.

The first source electrode 160, the first drain electrode 162, the second source electrode 164 and the second drain electrode 166 can have the same layer and the same material as each other. For example, the first source electrode 160, the first drain electrode 162, the second source electrode 164 and the second drain electrode 166 can have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the first planarizing layer 168 can have a single layer or a multiple layer of an organic insulating material such as photoacryl and benzocyclobutene (BCB).

The first semiconductor layer 136, the first gate electrode 140, the first source electrode 160 and the first drain electrode 162 can constitute the driving transistor Tdr, and the second semiconductor layer 152, the second gate electrode 156, the second source electrode 164 and the second drain electrode 166 can constitute the switching transistor Tsw.

A connecting electrode 170 is disposed on the first planarizing layer 168 corresponding to the first source electrode 160, and a second planarizing layer 172 is disposed on the connecting electrode 170 over the entire substrate 130.

The connecting electrode 170 is connected to the first source electrode 160 through a contact hole in the first planarizing layer 168.

For example, the connecting electrode 170 can have a triple layer of a metallic material such as aluminum (Al) and titanium (Ti).

For example, the second planarizing layer 172 can have a single layer or a multiple layer of an organic insulating material such as photoacryl and benzocyclobutene (BCB).

A first electrode 174 is disposed on the second planarizing layer 172 corresponding to the connecting electrode 170, and a bank layer 176 is disposed on the first electrode 174.

The first electrode 174 is connected to the connecting electrode 170 through a contact hole in the second planarizing layer 172.

For example, the first electrode 174 can be an anode and can have a single layer or a multiple layer of a transparent conductive material such as indium tin oxide (ITO) and indium zinc oxide (IZO) or an opaque metallic material such as aluminum (Al), silver (Ag), copper (Cu), lead (Pb), molybdenum (Mo), titanium (Ti) and an alloy thereof.

The bank layer 176 covers an edge portion of the first electrode 174 and has an opening exposing a central portion of the first electrode 174.

For example, the bank layer 176 can have a single layer or a multiple layer of an organic insulating material such as photoacryl and benzocyclobutene (BCB).

A spacer 178 is disposed on the bank layer 176, an emitting layer 180 is disposed on the spacer 178 over the entire substrate 130, and a second electrode 182 is disposed on the emitting layer 180 over the entire substrate 130.

For example, the spacer 178 can have a single layer or a multiple layer of an organic insulating material such as photoacryl and benzocyclobutene (BCB).

The emitting layer 180 contacts the first electrode 174 exposed through the opening of the bank layer 176, a sidewall of the opening of the bank layer 176, a top surface of the bank layer 176 and a side surface and a top surface of the spacer 178.

The emitting layer 180 can include a hole assisting layer such as a hole injecting layer and a hole transporting layer, an emitting material layer and an electron assisting layer such as an electron transporting layer and an electron injecting layer.

For example, the second electrode 182 can be a cathode and can have a single layer or a multiple layer of a transparent conductive material such as indium tin oxide (ITO) and indium zinc oxide (IZO) or a half-transmissive or opaque metallic material such as aluminum (Al), silver (Ag), copper (Cu), lead (Pb), magnesium (Mg), molybdenum (Mo), titanium (Ti) and an alloy thereof.

The first electrode 174, the emitting layer 180 and the second electrode 182 can constitute the light emitting diode Del.

An encapsulating layer 184 preventing a permeation of a moisture is disposed on the second electrode 182 over the entire substrate 130. The encapsulating layer 184 includes a first encapsulating layer 184a, a second encapsulating layer 184b and a third encapsulating layer 184c sequentially disposed on the second electrode 182.

For example, the first encapsulating layer 184a and the third encapsulating layer 184c can have a single layer or a multiple layer of an inorganic insulating material such as silicon oxide (SiO₂) and silicon nitride (SiNx), and the second encapsulating layer 184b can include an organic insulating material such as an acryl resin, an epoxy resin, a phenolic resin, a polyamide resin and a polyimide resin.

A third buffer layer 186 is disposed on the encapsulating layer 184 over the entire substrate 130, and a plurality of bridge patterns 188 spaced apart from each other are disposed on the third buffer layer 186.

The third buffer layer 186 can block a moisture or an oxygen permeating from an exterior. For example, the third buffer layer 186 can have a single layer or a multiple layer of an inorganic insulating material such as silicon oxide (SiO₂) and silicon nitride (SiNx).

For example, the plurality of bridge patterns 188 can have a single layer or a multiple layer of a transparent conductive material such as indium tin oxide (ITO) and indium zinc oxide (IZO) or a half-transmissive or opaque metallic material such as aluminum (Al), silver (Ag), copper (Cu), lead (Pb), magnesium (Mg), molybdenum (Mo), titanium (Ti) and an alloy thereof.

A third interlayer insulating layer 190 is disposed on the plurality of bridge patterns 188 over the entire substrate 130, a plurality of sensor patterns 192 spaced apart from each other are disposed on the third interlayer insulating layer 190, and a protecting layer 194 is disposed on the plurality of sensor patterns 192 over the entire substrate 130.

The plurality of sensor patterns 192 are connected to the plurality of bridge patterns 188 through contact holes in the third interlayer insulating layer 190. The plurality of sensor patterns 192 can sense a touch by detecting a change of a capacitance of the plurality of sensor patterns 192 according to the touch. The plurality of bridge patterns 188 and the plurality of sensor patterns 192 can be disposed in the display area DA and sensing a touch.

For example, the third interlayer insulating layer 190 can have a single layer or a multiple layer of an inorganic insulating material such as silicon oxide (SiO₂) and silicon nitride (SiNx) or an organic insulating material such as photoacryl and benzocyclobutene (BCB).

For example, the plurality of sensor patterns 192 can have a single layer or a multiple layer of a transparent conductive material such as indium tin oxide (ITO) and indium zinc oxide (IZO) or a half-transmissive or opaque metallic material such as aluminum (Al), silver (Ag), copper (Cu), lead (Pb), magnesium (Mg), molybdenum (Mo), titanium (Ti) and an alloy thereof.

For example, the protecting layer 194 can have a single layer or a multiple layer of an inorganic insulating material such as silicon oxide (SiO₂) and silicon nitride (SiNx) or an organic insulating material such as photoacryl and benzocyclobutene (BCB).

The data driving unit 122 is connected to the display panel 128 through a flexible circuit such as a chip on film (COF). For a narrow bezel, the data driving unit 122 can be disposed under a rear surface of the display panel 128 by bending the flexible circuit.

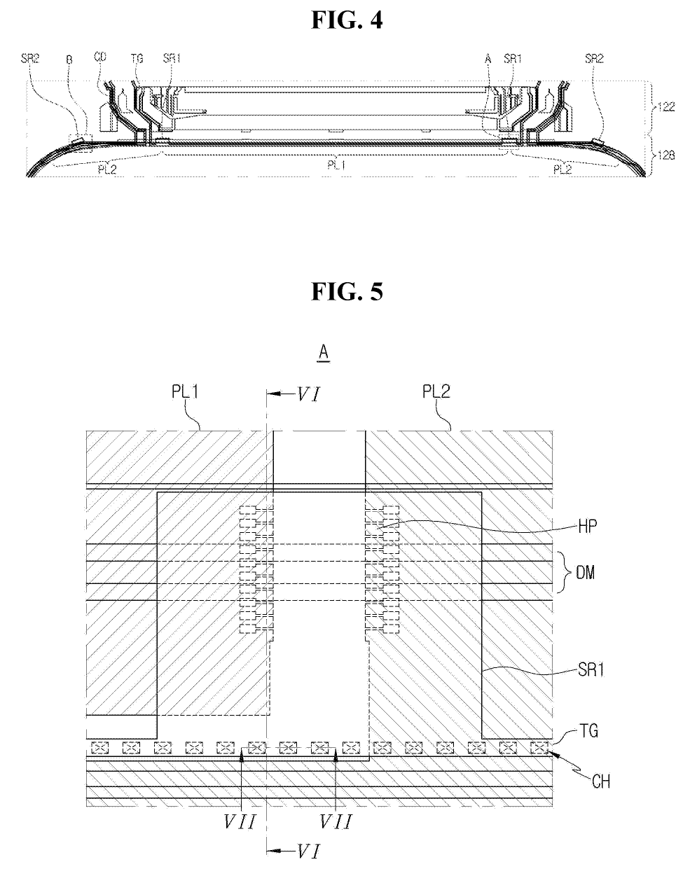

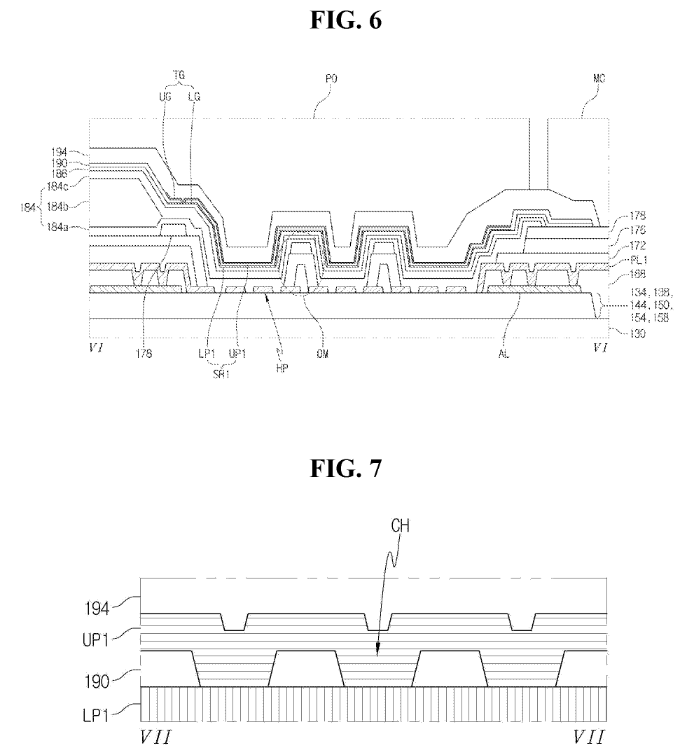

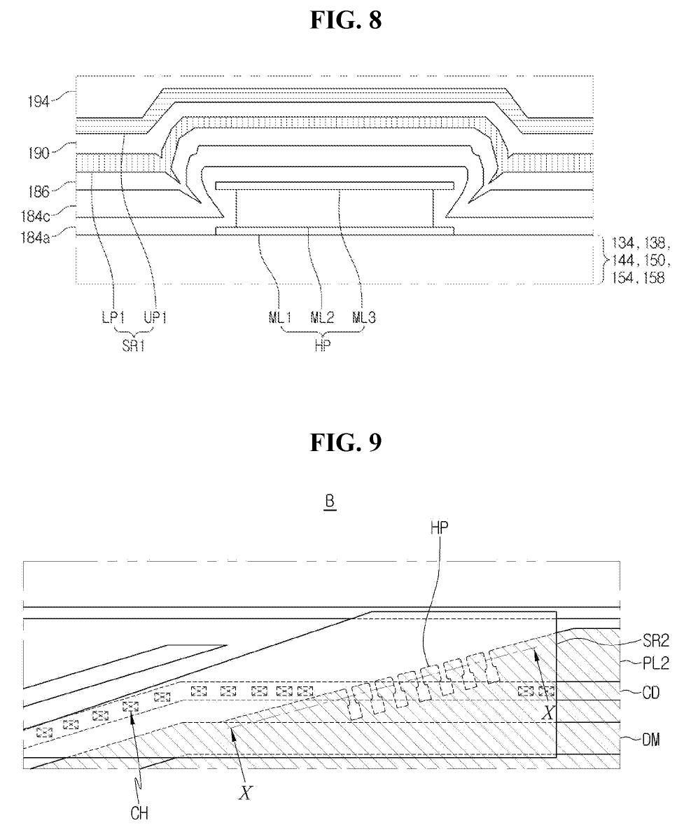

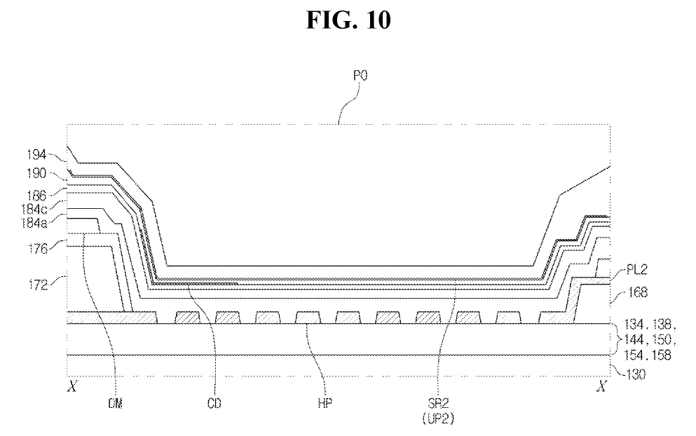

FIG. 4 is a plan view showing a display panel and a data driving unit of a display device according to an embodiment of the present disclosure, FIG. 5 is a magnified view of a portion A of FIG. 4, FIG. 6 is a cross-sectional view taken along a line VI-VI of FIG. 5, and FIG. 7 is a cross-sectional view taken along a line VII-VII of FIG. 5. FIG. 8 is a cross-sectional view showing a hammer pattern and a first stress relieving pattern of a display device according to an embodiment of the present disclosure, FIG. 9 is a magnified view of a portion B of FIG. 4, and FIG. 10 is a cross-sectional view taken along a line X-X of FIG. 9.

In FIG. 4, the data driving unit 122 of the display device 110 is connected to the display panel 128.

The data driving unit 122 supplies the high level signal Vdd and the low level signal Vss through first and second power lines PL1 and PL2, respectively. The first power line PL1 can be disposed in a central region of an upper non-display area NDA of the display panel 128, and the second power line PL2 can be disposed at both sides of the first power line PL1 of the upper non-display area NDA of the display panel 128.

For example, the first and second power lines PL1 and PL2 can have the same layer and the same material as the connecting electrode 170.

A hammer pattern HP of an uneven shape is disposed at facing sides of the first and second power lines PL1 and PL2 in a region where the first and third encapsulating layers 184a and 184c are disposed without the second encapsulating layer 184b.

For example, the hammer pattern HP can be disposed at both sides of the first power line PL1 in the central region of the upper non-display area NDA of the display panel 128 and at both sides of the second power line PL2 in the side regions of the upper non-display area NDA of the display panel 128.

A first stress relieving pattern SR1 is disposed on the hammer pattern HP of the opposite sides of the first and second power lines PL1 and PL2 of a portion A corresponding to the both sides of the first power line PL1, and a second stress relieving pattern SR2 is disposed on the hammer pattern HP of the other side of the second power line PL2 of a portion B corresponding to the other side of the second power line PL2. The first stress relieving pattern SR1 can cover the hammer pattern HP at facing sides of the first and second power lines PL1 and PL2. The second stress relieving pattern SR2 can cover the hammer pattern HP at another side of the second power line PL2.

For preventing a noise due to an external electric field such as a static electricity, a ground voltage is applied to a ground line TG. The ground line TG can be disposed at both sides of the outermost ones of a plurality of touch lines transmitting a touch signal to surround the non-display area NDA at upper, lower, left and right sides of the display panel 128.

For example, the ground line TG can include a lower ground layer LG (of FIG. 6) and an upper ground layer UG (of FIG. 6), and the upper ground layer UG can be connected to the lower ground layer LG through a contact hole in the third interlayer insulating layer 190. The lower ground layer LG can have the same layer and the same material as the plurality of bridge patterns 188, and the upper ground layer UG can have the same layer and the same material as the plurality of sensor patterns 192.

The first stress relieving pattern SR1 and the ground line TG can be connected to each other.

A detecting voltage is applied to a crack detecting line CD. Resistances of the crack detecting line CD are measured before and after a crack is generated, and it is judged by comparing the resistances whether the crack is generated. The crack detecting line CD can be disposed outside the ground line TG to surround left, right and lower sides of the display panel 128. The crack detecting line CD can be in the non-display area NDA at the left and right sides of the display panel 128.

For example, the crack detecting line CD can have the same layer and the same material as the plurality of bridge patterns 188.

The second stress relieving pattern SR2 and the crack detecting line CD can be connected to each other. The second stress relieving pattern SR2 can have a same layer and a same material as the plurality of sensor patterns 192.

In FIG. 5, the first power line PL1 transmitting the high level signal Vdd is disposed in the central region of the upper non-display area NDA of the display panel 128, and the second power line PL2 separated from the first power line PL1 and transmitting the low level signal Vss is disposed at both sides of the first power line PL1.

A dam DM extending along a horizontal direction is disposed on the first and second power lines PL1 and PL2.

The hammer pattern HP of an uneven shape is disposed at facing sides of the first and second power lines PL1 and PL2 in a region where the first and third encapsulating layers 184a and 184c are disposed without the second encapsulating layer 184b. The hammer pattern HP increases a length of one side of each of the first and second power lines PL1 and PL2 which is a permeation path of an impurity such as a moisture or an oxygen of an exterior to prevent permeation of an impurity.

The first stress relieving pattern SR1 is disposed on the hammer pattern HP of the first and second power lines PL1 and PL2 of the portion A. The first stress relieving pattern SR1 covers a seam of the first and third encapsulating layers 184a and 184c on the hammer pattern HP to alleviate a stress of the first and third encapsulating layers 184a and 184c and to improve a reliability.

The first stress relieving pattern SR1 includes a first lower relieving layer LP1 (of FIG. 6) and a first upper relieving layer UP1 (of FIG. 6). The first lower reliving layer LP1 can have the same layer and the same material as the plurality of bridge patterns 188, and the first upper relieving layer UP1 can have the same layer and the same material as the plurality of sensor patterns 192.

The ground line TG extending along a horizontal direction is disposed at a lower portion of the first stress relieving pattern SR1. The first relieving pattern SR1 can be connected to the ground line TG to receive the ground voltage.

For example, the first lower relieving layer LP1 and the first upper relieving layer UP1 of the first stress relieving pattern SR1 can be connected to the lower ground layer LG and the upper ground layer UG, respectively, of the ground line TG.

For preventing generation of a step difference of the first stress relieving pattern SR1 due to a step difference of a contact hole CH, a contact hole for connecting the first lower relieving layer LP1 and the first upper relieving layer UP1 of the first stress relieving pattern SR1 is not disposed in the first stress relieving pattern SR1. Instead, the first lower relieving layer LP1 and the first upper relieving layer UP1 of the first stress relieving pattern SR1 are connected to each other through the lower ground layer LG and the upper ground layer UG of the ground line TG.

In FIGS. 6 and 7, the first buffer layer 134, the first gate insulating layer 138, the first interlayer insulating layer 144, the second buffer layer 150, the second gate insulating layer 154 and the second interlayer insulating layer 158 are sequentially disposed on the substrate 130 of the portion A, and can be sequentially disposed under the hammer pattern HP, and an auxiliary line AL is disposed on the second interlayer insulating layer 158 of each of upper and lower edge portions of the non-display area NDA.

The auxiliary line AL can have the same layer and the same material as the first source electrode 160, the first drain electrode 162, the second source electrode 164 and the second drain electrode 166.

The first planarizing layer 168 is disposed on the auxiliary line AL, and the first power line PL1 having the hammer pattern HP at both sides thereof is disposed on the first planarizing layer 168.

The hammer pattern HP is disposed on the second interlayer insulating layer 158. The first power line PL1 on the first planarizing layer 168 can be connected to the auxiliary line AL through a contact hole in the first planarizing layer 168.

The second planarizing layer 172 and the bank layer 176 are sequentially disposed on the first power line PL1 corresponding to the auxiliary line AL and on the first power line PL1 corresponding to the hammer pattern HP.

The spacer 178 is disposed on the bank layer 176 corresponding to the auxiliary line AL, and the dam DM constituted by the second planarizing layer 172, the bank layer 176 and the spacer 178 is disposed on the hammer pattern HP.

The first encapsulating layer 184a is disposed on the spacer 178 and the dam DM over the entire substrate 130, and the second encapsulating layer 184b is disposed on the first encapsulating layer 184a corresponding to the display area DA. The third encapsulating layer 184c is disposed on the second encapsulating layer 184b over the entire substrate 130, and the third buffer layer 186 is disposed on the third encapsulating layer 184c over the entire substrate 130. The first encapsulating layer 184a, the third encapsulating layer 184c and the third buffer layer 186 can be disposed between the hammer pattern HP and the first lower relieving layer LP1. The third interlayer insulating layer 190 can be disposed between the first lower relieving layer LP1 and the first upper relieving layer UP1.

As a result, the first and third encapsulating layers 184a and 184c without the second encapsulating layer 184b are disposed on the hammer pattern HP and the first power line PL1 corresponding to the hammer pattern HP.

The lower ground layer LG is disposed on the third buffer layer 186 corresponding to the auxiliary line AL, the first lower relieving layer LP1 is disposed on the third buffer layer 186 corresponding to the hammer pattern HP, and the third interlayer insulating layer 190 is disposed on the lower ground line LG and the first lower relieving layer LP1.

The lower ground line LG and the first lower relieving layer LP1 can be connected to each other and can have the same layer and the same material as the plurality of bridge patterns 188.

The upper ground layer UG is disposed on the third interlayer insulating layer 190 corresponding to the auxiliary line AL, and the first upper relieving layer UP1 is disposed on the third interlayer insulating layer 190 corresponding to the hammer pattern HP.

The upper ground layer UG and the first upper relieving layer UP1 can be connected to each other and can have the same layer and the same material as each other.

The lower ground layer LG and the upper ground layer UG constitute the ground line TG, and the upper ground layer UG is connected to the lower ground layer LG through a contact hole CH in the third interlayer insulating layer 190.

The first lower relieving layer LP1 and the first upper relieving layer UP1 constitute the first stress relieving pattern SR1.

The protecting layer 194 is disposed on the upper ground layer UG and the first upper relieving layer UP1, a polarizing plate PO is disposed on the protecting layer 194 corresponding to the first stress relieving pattern SR1, and a micro coating layer MC is disposed on an end portion of the protecting layer 194 and the flexible circuit.

In FIG. 8, the hammer pattern HP has a triple layer of first, second and third metal layers ML1, ML2 and ML3 sequentially disposed on the second interlayer insulating layer 158.

For example, each of the first and third metal layers ML1 and ML3 can include titanium (Ti), and the second metal layer ML2 can include aluminum (Al).

The second metal layer ML2 is etched greater than the first and third metal layers ML1 and ML3 due to an etch rate difference of the first and third metal layer ML1 and ML3 and the second metal layer ML2. As a result, the hammer pattern HP has an overhang structure such that end portions of the first and third metal layers ML1 and ML3 protrude from an end portion of the second metal layer ML2.

The first and third encapsulating layers 184a and 184c on the hammer pattern HP and the third buffer layer 186 can have a seam, and a crack can be generated from the seam. In the display device 110 according to an embodiment of the present disclosure, the first lower relieving layer LP1 and the first upper relieving layer UP1 of the first stress relieving pattern SR1 is disposed on the third buffer layer 186 corresponding to the hammer pattern HP. As a result, the first stress relieving pattern SR1 covers and protects the seam of the first and third encapsulating layers 184a and 184c and the third buffer layer 186. Further, the first stress relieving pattern SR1 alleviates a stress of the first and third encapsulating layers 184a and 184c and the third buffer layer 186 to improve a reliability of the display device 110.

In FIG. 9, the second power line PL2 transmitting the low level signal Vss is disposed in the side regions of the upper non-display area NDA of the display panel 128.

The dam DM extending along a horizontal direction is disposed on the second power line PL2.

The hammer pattern HP of an uneven shape is disposed at the other side of the second power line PL2 in a region where the first and third encapsulating layers 184a and 184c are disposed without the second encapsulating layer 184b. The hammer pattern HP increases a length of one side of the second power line PL2 which is a permeation path of an impurity such as a moisture or an oxygen of an exterior to prevent permeation of an impurity.

The crack detecting line CD extending along a horizontal direction is disposed on the hammer pattern HP of the second power line PL2 of the portion B, and the second stress relieving pattern SR2 is disposed on the crack detecting line CD corresponding to the hammer pattern HP.

The second stress relieving pattern SR2 covers a seam of the first and third encapsulating layers 184a and 184c on the hammer pattern HP to alleviate a stress of the first and third encapsulating layers 184a and 184c and to improve a reliability.

The second stress relieving pattern SR2 includes a second upper relieving layer UP2 (of FIG. 10). The second upper reliving layer UP2 can have the same layer and the same material as the plurality of sensor patterns 192.

The second stress relieving pattern SR2 can be connected to the crack detecting line CD through a contact hole CH separated from the hammer pattern HP to receive a detection voltage.

For example, the second upper relieving layer UP2 of the second stress relieving pattern SR2 can be connected to the crack detecting line CD through the contact hole CH in the third interlayer insulating layer 190.

For preventing generation of a step difference of the second stress relieving pattern SR2 due to a step difference of the contact hole CH, a contact hole for connecting the second upper relieving layer UP2 of the second stress relieving pattern SR2 and the crack detecting line CD is not disposed in the second stress relieving pattern SR2. Instead, the second upper relieving layer UP2 of the second stress relieving pattern SR2 and the crack detecting line CD are connected to each other through the contact hole CH separated from the hammer pattern HP.

In FIG. 10, the first buffer layer 134, the first gate insulating layer 138, the first interlayer insulating layer 144, the second buffer layer 150, the second gate insulating layer 154 and the second interlayer insulating layer 158 are sequentially disposed on the substrate 130 of a central portion of the portion B, and the first buffer layer 134, the first gate insulating layer 138, the first interlayer insulating layer 144, the second buffer layer 150, the second gate insulating layer 154, the second interlayer insulating layer 158 and the first planarizing layer 168 are sequentially disposed on the substrate 130 of an edge portions of the portion B.

The second power line PL2 having the hammer pattern HP is disposed on the second interlayer insulating layer 158 of the edge portions of the non-display area NDA and the first planarizing layer 168, and the hammer pattern HP is disposed on the second interlayer insulating layer 158.

The second planarizing layer 172 and the bank layer 176 are sequentially disposed on the second power line PL2 not having the hammer pattern HP, and the dam DM is disposed on the bank layer 176 corresponding to the second power line PL2 not having the hammer pattern HP.

The first encapsulating layer 184a is disposed on the dam DM over the entire substrate 130, the third encapsulating layer 184c is disposed on the first encapsulating layer 184a over the entire substrate 130, and the third buffer layer 186 is disposed on the third encapsulating layer 184c over the entire substrate 130.

As a result, the first and third encapsulating layers 184a and 184c without the second encapsulating layer 184b are disposed on the hammer pattern HP and the first power line PL1 corresponding to the hammer pattern HP.

The crack detecting line CD is disposed on the third buffer layer 186 corresponding to the second power line PL2, and the third interlayer insulating layer 190 is disposed on the crack detecting line CD over the entire substrate 130.

The crack detecting line CD can have the same layer and the same material as the plurality of bridge patterns 188.

The second upper relieving layer UP2 of the second stress relieving pattern SR2 is disposed on the third interlayer insulating layer 190 corresponding to the hammer pattern HP.

The second upper relieving layer UP2 can have the same layer and the same material as the plurality of sensor patterns 192.

The second upper relieving layer UP2 is connected to the crack detecting line CD through a contact hole CH in the third interlayer insulating layer 190.

The protecting layer 194 is disposed on the second upper relieving layer UP2, and the polarizing plate PO is disposed on the protecting layer 194 corresponding to the second stress relieving pattern SR2.

Consequently, in the display device 110 according to an embodiment of the present disclosure, the first lower relieving layer LP1 and the first upper relieving layer UP1 of the first stress relieving pattern SR1 and the second upper relieving layer UP2 of the second stress relieving pattern SR2 are disposed on the third buffer layer 186 corresponding to the hammer pattern HP. As a result, the first and second stress relieving patterns SR1 and SR2 cover and protect the seam of the first and third encapsulating layers 184a and 184c and the third buffer layer 186. Further, a stress of the first and third encapsulating layers 184a and 184c and the third buffer layer 186 is alleviated, and a reliability of the display device 110 is improved. In addition, generation of the crack is minimized or prevented, and a display quality is improved.

It will be apparent to those skilled in the art that various modifications and variation can be made in the present disclosure without departing from the scope of the disclosure. Thus, it is intended that the present disclosure cover the modifications and variations of this disclosure provided they come within the scope of the appended claims and their equivalents.

WHAT IS CLAIMED IS:

1. A display device, comprising:
a display panel having a display area and a non-display area at a periphery of the display area;
a plurality of gate lines and a plurality of data lines in the display area, the plurality of gate lines and the plurality of data lines crossing each other to define a plurality of subpixels;
at least one thin film transistor in each of the plurality of subpixels;
a first power line and a second power line in the non-display area, each of the first and second power lines having a hammer pattern of an uneven shape; and
a first stress relieving pattern covering the hammer pattern at facing sides of the first and second power lines.

2. The display device of claim 1, further comprising:
a ground line in the non-display area at different sides of the display panel;
a crack detecting line in the non-display area at two opposite sides of the display panel; and
a plurality of bridge patterns and a plurality of sensor patterns in the display area and configured to sense a touch.

3. The display device of claim 2, wherein the first stress relieving pattern includes a first lower relieving layer and a first upper relieving layer on the first lower relieving layer.

4. The display device of claim 3, wherein the ground line includes a lower ground layer and an upper ground layer on the lower ground layer, the upper ground layer connected to the lower ground layer through a contact hole, and
wherein the first lower relieving layer and the first upper relieving layer are connected to the lower ground layer and the upper ground layer, respectively.

5. The display device of claim 4, wherein the first lower relieving layer and the lower ground layer have a same layer and a same material as the plurality of bridge patterns, and
wherein the first upper relieving layer and the upper ground layer have a same layer and a same material as the plurality of sensor patterns.

6. The display device of claim 3, wherein a first buffer layer, a first gate insulating layer, a first interlayer insulating layer, a second buffer layer, a second gate insulating layer and a second interlayer insulating layer are sequentially disposed under the hammer pattern,
wherein a first encapsulating layer, a third encapsulating layer and a third buffer layer are disposed between the hammer pattern and the first lower relieving layer,
wherein a third interlayer insulating layer is disposed between the first lower relieving layer and the first upper relieving layer, and
wherein a protecting layer is disposed on the first upper relieving layer.

7. The display device of claim 2, further comprising a second stress relieving pattern covering the hammer pattern at another side of the second power line.

8. The display device of claim 7, wherein the second stress relieving pattern is connected to the crack detecting line through a contact hole.

9. The display device of claim 8, wherein the crack detecting line has a same layer and a same material as the plurality of bridge patterns, and
wherein the second stress relieving pattern has a same layer and a same material as the plurality of sensor patterns.

10. The display device of claim 1, wherein each of the first and second power lines includes first, second and third metal layers.

11. The display device of claim 6, wherein the plurality of sensor patterns are connected to the plurality of bridge patterns through contact holes in the third interlayer insulating layer.

12. The display device of claim 6, wherein the hammer pattern has a triple layer including first, second and third metal layers sequentially disposed on the second interlayer insulating layer.

13. The display device of claim 12, wherein each of the first and third metal layers includes titanium, and the second metal layer includes aluminum.

14. The display device of claim 12, wherein end portions of the first and third metal layers protrude from an end portion of the second metal layer.

15. The display device of claim 6, wherein the first lower relieving layer and the first upper relieving layer are disposed on the third buffer layer corresponding to the hammer pattern.

16. The display device of claim 6, further comprising an auxiliary line disposed on the second interlayer insulating layer of each of upper and lower edge portions of the non-display area.

17. The display device of claim 16, wherein the ground line includes a lower ground layer and an upper ground layer on the lower ground layer,
wherein the lower ground layer is disposed on the third buffer layer corresponding to the auxiliary line,
wherein the first lower relieving layer is disposed on the third buffer layer corresponding to the hammer pattern, and
wherein the third interlayer insulating layer is disposed on the lower ground line and the first lower relieving layer.

18. A display device, comprising:
a display panel having a display area and a non-display area adjacent to the display area, the display area including a plurality of subpixels configured to display images;
a first power line and a second power line both disposed in the non-display area, each of the first and second power lines having a hammer pattern with an uneven shape;
a first stress relieving pattern disposed on the hammer pattern at facing sides of the first and second power lines; and
a second stress relieving pattern disposed on the hammer pattern at another side of the second power line.

19. The display device of claim 18, further comprising:
a ground line disposed in the non-display area at sides of the display panel; and
a crack detecting line disposed in the non-display area at two opposite sides of the display panel.

20. The display device of claim 19, wherein the first stress relieving pattern and the ground line are connected to each other, and
wherein the second stress relieving pattern is connected to the crack detecting line through a contact hole.
